(19) United States
(12) Patent Application Publication
(10) Pub. No.: US 2008/0096362 A1
(43) Pub. Date: Apr. 24, 2008

(54) Plasma display panel and manufacturing method of the same

(75) Inventors: Hideaki Hirabara, Miyazaki-shi (JP); Akira Shimoyoshi, Miyazaki-shi (JP); Motonari Kifune, Miyazaki-shi (JP)

Correspondence Address: STAAS & HALSEY LLP, SUITE 700, 1201 NEW YORK AVENUE, N.W., WASHINGTON, DC, 20005, US

(73) Assignee: FUJITSU HITACHI PLASMA DISPLAY LIMITED, Miyazaki (JP)

(21) Appl. No.: 11/730,879

(22) Filed: Apr. 4, 2007

(30) Foreign Application Priority Data
Oct. 23, 2006 (JP) 2006-287998

(51) Int. Cl. H01L 21/20

(52) U.S. Cl. 438/396

(57) ABSTRACT

A plasma display panel includes a sealing member that encloses a gas filled space, a first substrate and a second substrate that sandwich the gas filled space and the sealing member, a first insulator layer that is sandwiched between the first substrate and the sealing member, and a second insulator layer that is sandwiched between the second substrate and the sealing member. Materials and thicknesses of the first insulator layer and the second insulator layer are selected so that etching time of the two insulator layers until etching depth reaches the thicknesses of the insulator layers are the same time period under conditions that one side of each of the insulator layers in the thickness direction is exposed to etchant and that the same etching method is used for the insulator layers.

### BACKGROUND OF THE INVENTION

1. Field of the Invention

The present invention relates to a plasma display panel that is a gas discharge display device and a manufacturing method of the same. More specifically, the present invention relates to a sealing structure for a gas filled space and formation of the structure.

2. Description of the Prior Art

A plasma display panel is equipped with a pair of glass substrates 11 and 21 that are larger than a screen 50 and are opposed to each other as shown in FIG. 1. These glass substrates 11 and 21 are bonded to each other with a frame-like sealing member 35 that encloses the screen 50, so as to form a flat vessel that contains discharge gas. In general, electrodes X, Y and A are arranged on inner surfaces of the glass substrates 11 and 21. The electrodes X and Y on one of the glass substrates 11 and 21 are arranged to cross the electrodes A on the other glass substrate. The electrodes X, Y and A extend from the screen 50 to vicinities of edges of the glass substrates 11 and 21 that support the electrodes. The edge of each of the glass substrates 11 and 21 at which the electrodes are extended protrudes from an edge of the other glass substrate 21 or 11 by 5-10 mm so that end portions of the electrodes can be exposed and connected to a circuit board (not shown).

As known well, an AC type plasma display panel has a dielectric layer (an insulator layer) that covers the electrodes for sustain discharge. The dielectric layer works as a memory for storing data for display, and it is utilized as a protection film for preventing the electrodes from oxidation in a stage of manufacturing the plasma display panel. Therefore, the dielectric layer is formed so as to cover the entire length of the electrode that extends from the screen. After bonding of the substrates with the sealing member is completed, a part of the dielectric layer outside the sealing member is removed by wet etching so that the end portions of the electrodes are exposed.

As to the dielectric layer that covers the entire electrodes, Japanese unexamined patent publication No. 7-65729 discloses a dielectric layer having two parts made of different materials. A part of the dielectric layer that is to be removed in the final stage of manufacturing is made of low melting point glass having the composition that is easily etched, while a main part of the same over the entire screen is made of low melting point glass having good transparency. In addition, Japanese unexamined patent publication No. 9-50769 discloses a dielectric layer made up of two parts having different thicknesses. The dielectric layer includes an under layer that covers the entire electrodes and an over layer that is formed on the under layer so as not to cover end portions of the electrodes. The part to be removed in the final stage of manufacturing is made of only the under layer, so it is thin. The main part over the entire screen is made of the under layer and the over layer, so it is thick.

The above-mentioned plasma display panels described in Japanese unexamined patent publication No. 7-65729 and No. 9-50769 have a three electrode structure, but they do not have a structure in which the dielectric layer that works as the electrode protection film is arranged on both substrates. Here, the three electrode structure means a panel structure that includes first and second electrodes for generating the sustain discharge and third electrodes for generating address discharge with the first or the second electrode, in which the first and the second electrodes are arranged in parallel on one of the substrates while the third electrodes are arranged on the other substrate so as to cross the first and the second electrodes. In contrast, as to the plasma display panels described in the above-mentioned Japanese unexamined patent publications, the substrate that supports the third electrode has fluorescent materials that cover the third electrode but does not have a dielectric layer as an electrode protection film.

On the contrary, a typical plasma display panel in these years has a first dielectric layer that covers the first and the second electrodes arranged on one of the substrates and a second dielectric layer that covers the third electrode arranged on the other substrate as shown in Japanese unexamined patent publication No. 2005-149937, for example. This structure for covering the third electrode explicitly has become adopted because of increasing requirement for preventing deterioration of the third electrode due to discharge so as to maintain reliability in driving the plasma display panel.

The first dielectric layer needs electrification capacity for forming wall charge that is necessary for AC drive. For this reason, the first dielectric layer is formed to have relatively large thickness. The thickness of a typical first dielectric layer made of low melting point glass having a dielectric constant of 11 to 13 is approximately 20 to 30 microns. On the other hand, the second dielectric layer is not required to be as thick as the first dielectric layer because the second dielectric layer basically does not need the electrification capacity. The thickness of a typical second dielectric layer is approximately a half of thickness of the first dielectric layer.

As described above, each of the first and the second dielectric layers covers the entire of the corresponding electrodes for protecting the same in the stage of manufacturing the plasma display panel. In the etching process after bonding the substrates with the sealing member, parts of the first dielectric layer and the second dielectric layer that protrude from the sealing member are removed concurrently. Thus, end portions of the first, the second and the third electrodes are exposed.

There is a tendency that sealing performance of the gas filled space can be lowered more easily in a plasma display panel that has the dielectric layers on both the first and the second substrates than in a plasma display panel that has the dielectric layer only on one of the substrates. According to the inventors' study of causes of deterioration in the sealing performance, it was found that excessive etching of the dielectric layer when removing it in part for exposing the electrode causes insufficient bond of adhesion between the sealing member and the substrate. More specific description is as follows.

FIGS. 2A and 2B show a sectional structure of a sealing portion of a conventional plasma display panel schematically. FIG. 2A shows a part corresponding to a cross section cut along the line a-a′ in FIG. 1, and FIG. 2B shows a part corresponding to a cross section cut along the line b-b′ in FIG. 1. As shown in the drawings, the glass substrate 11 on the front side supports the first electrodes X, the second electrodes Y and a first dielectric layer 17. Each of the first and the second electrodes X and Y is made up of a transparent conductor 13 that forms a surface discharge gap and a metal band 14 that is a power supplying bus. The glass substrate 21 on the rear side supports the third electrodes A, a second dielectric layer 22, partitions 23 that divide the gas filled space 30, and fluorescent materials 25 for color display. The glass substrate 11 and the glass substrate 21 are bonded to each other via the sealing member 35 such as sealing low melting point glass. The first dielectric layer 17 is sandwiched between the glass substrate 11 and the sealing member 35, and the second dielectric layer 22 is sandwiched between the glass substrate 21 and the sealing member 35. Furthermore, a protection film having a large secondary emission coefficient is formed on the surface of the first dielectric layer 17, but its thickness is very small like 5,000 angstroms. Therefore, a part of the protection film that contacts the sealing member 35 may be broken when the bonding is performed and may not contribute to the bonding substantially.

When the bonding of the substrates with the sealing member 35 is finished in the manufacturing stage of the plasma display panel, the first dielectric layer 17 and the second dielectric layer 22 are extended to the periphery of the sealing member 35 as shown with the dot and dash line in FIGS. 2A and 2B so that the end portions of the electrodes X, Y and A are not exposed.

In the wet etching process for exposing the end portions of the electrodes X, Y and A, an extending portion 17A of the first dielectric layer 17 and an extending portion 22A of the second dielectric layer 22 are etched concurrently. In this case, there is no or little difference between etching speeds of the dielectric layer 17 and the dielectric layer 22. It is because their materials are the same or similar.

Since the thickness T1 of the extending portion 17A is larger than the thickness T2 of the extending portion 22A, the extending portion 17A still remains when the extending portion 22A disappears in the etching process. Since the etching process continues until the extending portion 17A disappears, over etching proceeds on the dielectric layer 22 as time passes. As the dielectric layer 22 is etched more than a necessary extent, gaps 91 and 92 are generated between the sealing member 35 and the glass substrate 21 on the rear side as shown in FIGS. 2A and 2B. In addition, a gap 93 is also generated between the sealing member 35 and the glass substrate 11 as shown in FIG. 2B.

The gaps 91, 92 and 93 lower the bonding strength between the sealing member 35 and the glass substrate 21, so that reliability in sealing the gas filled space 30 is deteriorated. In addition, if the gaps 91, 92 and 93 extend and communicate with the gas filled space 30 via the interface between the sealing member 35 and the dielectric layer 22 in some place on the periphery of the screen, the sealing performance is lost at that time point.

### SUMMARY OF THE INVENTION

An object of the present invention is to provide a plasma display panel and a manufacturing method of the same that can obtain high reliability in sealing the gas filled space.

A plasma display panel according to an aspect of the present invention includes a sealing member that encloses a gas filled space, a first substrate and a second substrate that sandwich the gas filled space and the sealing member, a first insulator layer that is sandwiched between the first substrate and the sealing member, and a second insulator layer that is sandwiched between the second substrate and the sealing member. Materials and thicknesses of the first insulator layer and the second insulator layer are selected so that etching time of the two insulator layers until etching depth reaches the thicknesses of the insulator layers are the same time period under the conditions that one side of each of the insulator layers in a thickness direction is exposed to etchant and that the same etching method is used for the insulator layers.

A manufacturing method of a plasma display panel according to another aspect of the present invention includes assembling a sealing member that encloses a gas filled space, a first substrate and a second substrate that sandwich the gas filled space and the sealing member, a first insulator layer that is sandwiched between the first substrate and the sealing member, and a second insulator layer that is sandwiched between the second substrate and the sealing member, and removing an extending portion of a first substrate covering layer that includes the first insulator layer and is extended from an outer rim of the sealing member as well as an extending portion of a second substrate covering layer that includes the second insulator layer and is extended from an outer rim of the sealing member by using the same etching process. The method further includes the step of setting materials and thicknesses of the extending portion of the first substrate covering layer and the extending portion of the second substrate covering layer so that etching time for removing the former extending portion is equal to etching time for removing the latter extending portion.

If the etching time is the same, the first substrate covering layer and the second substrate covering layer can be etched equally so that over etching can be avoided.

According to an embodiment of the present invention, a material of the first insulator layer is the same as a material of the second insulator layer, and a thickness of the first insulator layer is the same as a thickness of the second insulator layer. If the materials are the same, etching speeds (etching rates) of them are also the same. Therefore, etching time is the same between the two layers having the same materials and the same thicknesses. In addition, if the materials are different but the etching speeds are the same, the etching time is the same between the two layers. Furthermore, even if the etching speeds are different, the etching time can be the same between the two layers by making the thicknesses of them different from each other.

According to the present invention, reliability in sealing the gas filled space can be improved.

### BRIEF DESCRIPTION OF THE DRAWINGS

FIG. 1 is a perspective view showing a general structure of a plasma display panel schematically.

FIGS. 2A and 2B are diagrams showing schematically a sectional structure of a sealing portion of a conventional plasma display panel.

FIGS. 3A and 3B are diagrams showing schematically a sectional structure of a sealing portion of a plasma display panel according to a first embodiment of the present invention.

FIGS. 4A and 4B are diagrams showing schematically a sectional structure of a sealing portion of a plasma display panel according to a second embodiment of the present invention.

### DESCRIPTION OF THE PREFERRED EMBODIMENTS

Hereinafter, embodiments of the present invention will be described with reference to the attached drawings. In the drawings, elements having the same function are denoted by the same reference signs for easy understanding of the characteristics of the structure.

### First Embodiment

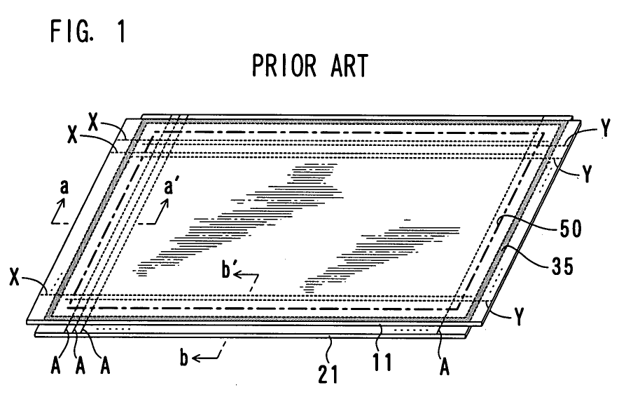

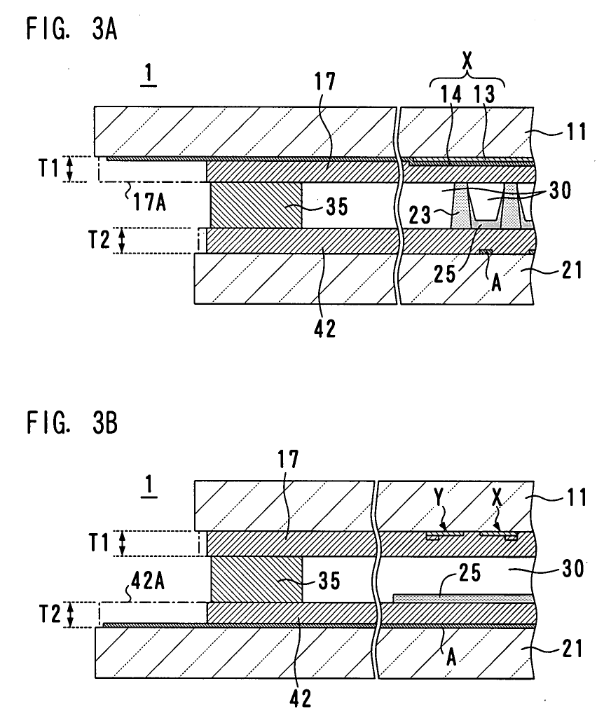

FIGS. 3A and 3B show schematically a sectional structure of a sealing portion of a plasma display panel according to a first embodiment of the present invention. FIG. 3A shows a part corresponding to a cross section cut along the line a-a′ in FIG. 1, and FIG. 3B shows a part corresponding to a cross section cut along the line b-b′ in FIG. 1.

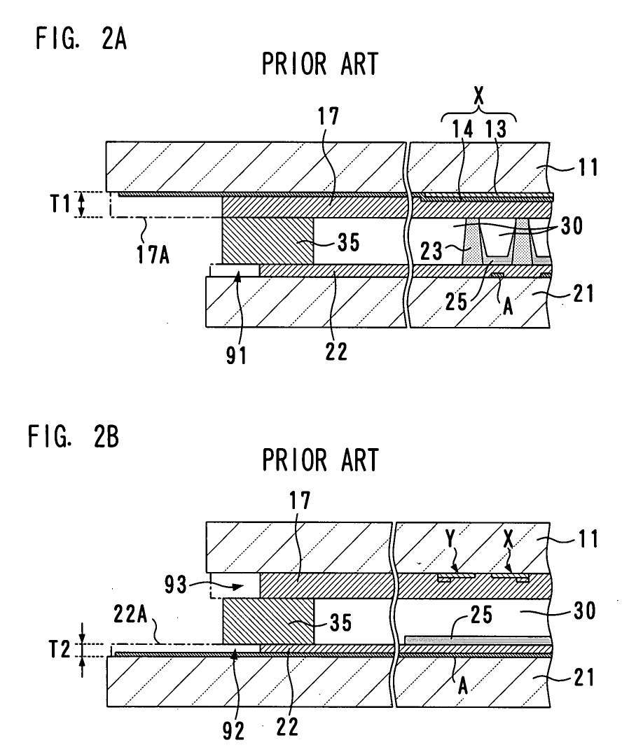

A plasma display panel 1 is equipped with a sealing member 35 that encloses a gas filled space 30, first and second substrates (glass substrates 11 and 21) that sandwich the gas filled space 30 and the sealing member 35, a dielectric layer (first insulator layer) 17 that is sandwiched between the first glass substrate 11 and the sealing member 35, and a dielectric layer (second insulator layer) 42 that is sandwiched between the second glass substrate 21 and the sealing member 35. The structure of the plasma display panel 1 is similar to that of the plasma display panel shown in FIGS. 2A and 2B except that the former includes the dielectric layer 42 instead of the dielectric layer 22 of the conventional plasma display panel shown in FIGS. 2A and 2B. Therefore, the following description will be focused mainly on the elements related to the characteristics of the present invention, and overlapping description for other elements will be omitted.

A dielectric layer 17 that is supported by the glass substrate 11 on the front side is an element for AC drive, and it covers first and second electrodes X and Y arranged in parallel over the entire screen. The dielectric layer 42 that is supported by the glass substrate 21 on the rear side covers third electrodes A over the entire screen so as to prevent the third electrodes A from deterioration due to discharge. Note that electrification of the dielectric layer 42 may be utilized positively for controlling address discharge and that the dielectric layer 42 may be utilized as a stopper in a sandblasting process for cutting and forming the partition 23.

The plasma display panel 1 has a characteristic that materials and thicknesses of the dielectric layer 17 and the dielectric layer 42 are selected so that etching time of the two layers until etching depth reaches the thicknesses of the layers are the same time period under the conditions that one side of each of the layers is exposed to etchant and that the same etching method is used for the layers. The etching process is not performed on the dielectric layer 17 and the dielectric layer 42 in the state shown in FIGS. 3A and 3B. Actually, the etching process is performed for exposing the electrode end portions in the stage of manufacturing the plasma display panel 1. In this case, materials and thicknesses of the dielectric layer 17 and the dielectric layer 42 are selected so that exposure of the electrodes X and Y on the front side and exposure of the electrodes A on the rear side can be completed substantially at the same time.

The manufacturing method of the plasma display panel 1 includes a step of forming layers of predetermined elements on the glass substrates 11 and 21, a step of bonding the glass substrates 11 and 21 with the sealing member 35, and a step of evacuating inside air via an air hole that is provided to the glass substrate 21 in advance and filling a gas instead. When the bonding of the substrates is finished in the manufacturing stage, the dielectric layer 17 and the dielectric layer 42 are extended to the periphery of the sealing member 35 as shown in FIGS. 3A and 3B with the dot and dash line so that the end portions of the electrodes X, Y and A are not exposed. The etching process for exposing the electrode end portions is performed after the bonding of the substrates and before or after the air evacuating step. Note that in the following description the dielectric layer in the state extended to the periphery of the sealing member 35 is referred to as a substrate covering layer so that it is distinguished from the dielectric layer after the etching process. The substrate covering layer on the front side is made up of the dielectric layer 17 and the extending portion 17A, while the substrate covering layer on the rear side is made up of the dielectric layer 42 and the extending portion 42A.

There are methods of forming the substrate covering layer, which include a method of applying glass paste onto the substrate by a die coat method, a spin coat method, a spray method, a screen printing method or the like and baking the same, and a method of sticking a laminating green sheet containing glass frit to the substrate and baking the same. It is preferable for good productivity to form the substrate covering layer to cover the entire mother glass having dimensions that includes a plurality of glass substrates and then to divide the mother glass into a plurality of glass substrate.

Concrete examples of the material, the thickness and the etching method of the substrate covering layer including the dielectric layers 17 and 42 are as follows.

### FIRST EXAMPLE

The same material was used for the dielectric layer 17 on the front side and the dielectric layer 42 on the rear side, and the thickness T1 of the dielectric layer 17 was set to the substantially same as the thickness T2 of the dielectric layer 42. The term “substantially” means that a difference between the thicknesses is within a range of manufacturing error like approximately a few percent, which can be regarded that the thicknesses are the same.

The material of the dielectric layer was low melting point glass made of glass frit that had the following composition and was burned at 600 degrees centigrade.

PbO: 70-75 weight percent

B₂O₃: 10-20 weight percent

SiO₂: 10-20 weight percent

Here, design dimensions of the thicknesses T1 and T2 were 30 microns.

The sealing member 35 was made of sealing low melting point glass (e.g., ASF-2000 made by Asahi Glass Co., Ltd.). Its pattern width was approximately 10 mm, and its thickness was approximately 150 microns in the bonded state.

A work was put in a shower room into which shower of etchant was supplied, which was nitric acid solution of molar concentration 6% at temperature 25 degrees centigrade. Thus, the extending portion 17A and the extending portion 42A were etched. The extending portions 17A and 42A were removed completely at substantially the same time. The etching time was three minutes.

### SECOND EXAMPLE

The thickness T1 of the dielectric layer 17 on the front side was substantially the same as the thickness T2 of the dielectric layer 42 on the rear side, while the material of the dielectric layer 17 was different from the material of the dielectric layer 42. However, the materials of the layers were selected so that the etching speeds of the layers were substantially the same. More specifically, material and thickness of the dielectric layer 17 were selected to be the same as those of the first example described above. Then, the dielectric layer 42 was made of low melting point glass having the following composition.

PbO: 60-65 weight percent

B₂O₃: 5-10 weight percent

SiO₂: 20-30 weight percent

The etching process was performed under the same condition as the first example. Then, the extending portions 17A and 42A were removed completely at substantially the same time.

### THIRD EXAMPLE

The material of the dielectric layer 42 on the rear side was selected to have smaller etching speed than the dielectric layer 17 on the front side, and the thickness T2 of the dielectric layer 42 was selected to be smaller than the thickness T1 of the dielectric layer 17.

The material of the dielectric layer 17 was the same as that in the first example, and the thickness T1 of the dielectric layer 17 was 30 microns. The dielectric layer 42 was low melting point glass having the following composition, and the thickness T2 of the dielectric layer 42 was 10 microns.

ZnO: 55-65 weight percent

B₂O₃: 20-30 weight percent

SiO₂: 5-10 weight percent

The etching process was performed under the same condition as the first example. Then, the extending portions 17A and 42A were removed completely at substantially the same time.

### Second Embodiment

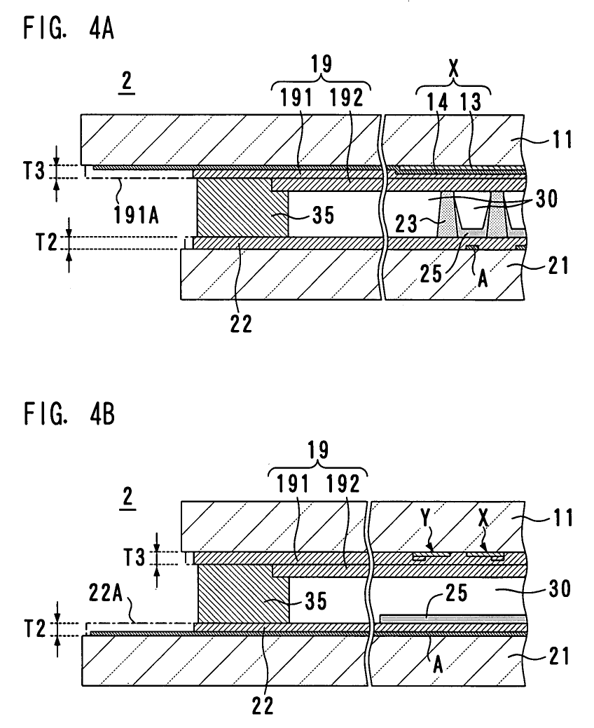

FIGS. 4A and 4B show schematically a sectional structure of a sealing portion of a plasma display panel according to a second embodiment of the present invention. FIG. 4A shows a part corresponding to a cross section cut along the line a-a′ in FIG. 1, and FIG. 4B shows a part corresponding to a cross section cut along the line b-b′ in FIG. 1.

A plasma display panel 2 is equipped with a sealing member 35 that encloses a gas filled space 30, first and second substrates (glass substrates 11 and 21) that sandwich the gas filled space 30 and the sealing member 35, a dielectric layer (first insulator layer) 191 that is sandwiched between the first glass substrate 11 and the sealing member 35, and a dielectric layer (second insulator layer) 22 that is sandwiched between the second glass substrate 21 and the sealing member 35.

The plasma display panel 2 has a characteristic that the dielectric layer 19 covering the electrodes X and Y on the front side has a double layer structure including the first dielectric layer (under layer) 191 and a second dielectric layer (over layer) 192. In addition, materials and thicknesses of the under layer 191 and the dielectric layer 22 on the rear side are selected so that etching time of the two layers until etching depth reaches the thicknesses of the layers are the same time period under the conditions that one side of each of the layers in the thickness direction is exposed to etchant and that the same etching method is used for the layers. The etching process is not performed on the under layer 191 and the dielectric layer 22 in the state shown in FIGS. 4A and 4B. Actually, the etching process is performed for exposing the electrode end portions in the stage of manufacturing the plasma display panel 2. In this case, materials and thicknesses of the under layer 191 and the dielectric layer 22 are selected so that exposure of the electrodes X and Y on the front side and exposure of the electrodes A on the rear side can be completed substantially at the same time.

The over layer 192 is an element for setting the thickness of the dielectric layer 19 to be large enough for adapting to the AC drive. The over layer 192 is disposed so as to extend over the entire screen and not to protrude from the outer rim of the sealing member 35. Although the over layer 192 contacts the sealing member 35 in FIGS. 4A and 4B, the over layer 192 may be separated from the sealing member 35 as long as it covers the entire screen. In addition, materials and thickness of the over layer 192 may be or may not be the same as those of the under layer.

When the bonding of the substrates is finished in the manufacturing stage of the plasma display panel 2, the under layer 191 and the dielectric layer 22 are extended to the periphery of the sealing member 35 as shown in FIGS. 4A and 4B with the dot and dash line so that the end portions of the electrodes X, Y and A are not exposed. The etching process for exposing the electrode end portions is performed after the bonding of the substrates. Note that here the under layer 191 and the dielectric layer 22 in the state extended to the periphery of the sealing member 35 are referred to as substrate covering layers so that they are distinguished from the layers after the etching process. The substrate covering layer on the front side is made up of the under layer 191 and the extending portion 191A, while the substrate covering layer on the rear side is made up of the dielectric layer 22 and the extending portion 22A.

There are methods of equalizing the etching time of the extending portions 191A and 22A, which are similar to the methods of the first to the third examples described above. In other words, it is sufficient to equalize materials and thicknesses T3 and T2 of the substrate covering layers on the front side and on the rear side, or to select materials having equal etching speed and equalize the thicknesses T3 and T2, or to make the thickness T3 and the thickness T2 different from each other in accordance with a difference of their etching speeds.

As to the embodiments described above, there is no special limitation of materials of the electrodes, the arrangement form of the same, the cell structure of the screen, and the like. The materials and the thicknesses T1, T2 and T3 of the dielectric layers 17, 19, 22 and 42, the material and the dimensions of the sealing member 35, the etchant, the type of the etching device, and the like are not limited to those exemplified above but can be modified within the scope in accordance with the spirit of the present invention, if necessary.

The present invention can be applied to various display devices that perform color displays with gas discharge, which include a display device of a data processing device such as a personal computer or a workstation, a flat type television set, a display device for a public display such as advertisement or guide information, and the like.

While example embodiments of the present invention have been shown and described, it will be understood that the present invention is not limited thereto, and that various changes and modifications may be made by those skilled in the art without departing from the scope of the invention as set forth in the appended claims and their equivalents.

What is claimed is:

1. A plasma display panel comprising:
a sealing member that encloses a gas filled space;
a first substrate and a second substrate that sandwich the gas filled space and the sealing member;
a first insulator layer that is sandwiched between the first substrate and the sealing member; and
a second insulator layer that is sandwiched between the second substrate and the sealing member, wherein
materials and thicknesses of the first insulator layer and the second insulator layer are selected so that etching time of the two insulator layers until etching depth reaches the thicknesses of the insulator layers are the same time period under conditions that one side of each of the insulator layers in a thickness direction is exposed to etchant and that the same etching method is used for the insulator layers.

2. The plasma display panel according to claim 1, wherein the material of the first insulator layer is the same as the material of the second insulator layer, and the thickness of the first insulator layer is the same as the thickness of the second insulator layer.

3. The plasma display panel according to claim 1, wherein the material of the first insulator layer is different from the material of the second insulator layer, an etching speed when the first insulator layer is etched is the same as an etching speed when the second insulator layer is etched, and the thickness of the first insulator layer is the same as the thickness of the second insulator layer.

4. The plasma display panel according to claim 1, wherein the material of the first insulator layer is different from the material of the second insulator layer, and the thickness of the first insulator layer is different from the thickness of the second insulator layer.

5. A method for manufacturing a plasma display panel, comprising:
assembling a sealing member that encloses a gas filled space, a first substrate and a second substrate that sandwich the gas filled space and the sealing member, a first insulator layer that is sandwiched between the first substrate and the sealing member, and a second insulator layer that is sandwiched between the second substrate and the sealing member; and
removing an extending portion of a first substrate covering layer that includes the first insulator layer and is extended from an outer rim of the sealing member as well as an extending portion of a second substrate covering layer that includes the second insulator layer and is extended from an outer rim of the sealing member by using the same etching process,
wherein the method includes the step of setting materials and thicknesses of the extending portion of the first substrate covering layer and the extending portion of the second substrate covering layer so that etching time for removing the former extending portion is equal to etching time for removing the latter extending portion.

6. The method according to claim 5, wherein the method further includes the step of forming the first substrate covering layer to have an under layer and an over layer, the under layer extending from the inside to the outside of an area where the sealing member is disposed and including the extending portion, the over layer overlapping the under layer except the outside of the area, so that the extending portion of the first substrate covering layer is thinner than the other portion of the same.
